(19) United States
(12) Patent Application Publication
(10) Pub. No.: US 2026/0352209 A1
(43) Pub. Date: Nov. 5, 2026

(54) INPUT/OUTPUT DRIVER OF TRANSMITTER CIRCUIT

(71) Applicant: TAIWAN SEMICONDUCTOR MANUFACTURING COMPANY LTD., HSINCHU (TW)

(72) Inventor: TUNG-TSUN CHEN, HSINCHU CITY (TW)

(21) Appl. No.: 19/194,050

(22) Filed: Apr. 30, 2025

(51) Int. Cl. H03K 17/687; H03K 19/20; H04B 1/04

(52) U.S. Cl. CPC H03K 17/6872; H03K 19/20; H04B 1/04

(57) ABSTRACT

A transmitter circuit is provided, which includes a control logic and a driving circuit. The control logic is configured to generate a data signal, a first resistance calibration signal, and a second resistance calibration signal. The driving circuit includes a plurality of stages, and each stage includes an input/output (I/O) driver and a pre-driver. The I/O driver includes a pull-up device and a pull-down device coupled to an I/O pad of the transmitter circuit through a first portion and a second portion of a resistor, respectively. The pre-driver includes a first logic gate which operates according to a respective bit of the first resistance calibration signal and the data signal; a second logic gate which operate according to a respective bit of the second resistance calibration signal and the data signal; first inverters configured to drive the pull-up device; and second inverters configured to drive the pull-down device.

### BACKGROUND

The progression of Low-Power Double Data Rate (LPDDR) memory standards has resulted in notable improvements in both data rates and power efficiency. Specifically, LPDDR5X is capable of achieving data rates of up to 9.6 Gbps while maintaining a low input/output (I/O) voltage of approximately 0.5 V. The upcoming LPDDR6 standard is anticipated to further enhance data rates, potentially reaching 14.4 Gbps or higher, while retaining a low I/O voltage comparable to that of LPDDR5X. The design of transmitter I/O drivers that are compatible with LPDDR5X and future revisions poses significant challenges due to the high data rates and reduced I/O voltages.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a semiconductor device 100 in accordance with some embodiments.

FIG. 2 is a block diagram of a driving stage of a semiconductor device in accordance with some embodiments.

FIG. 3 is a diagram of a driving stage of a transmitter circuit in accordance with some embodiments.

FIG. 4A is a waveform diagram of various signals within the transmitter circuit in FIG. 3.

FIG. 4B is an eye diagram of a data signal of the transmitter circuit in FIG. 3.

FIG. 4C is a circuit diagram illustrating the pull-up device and the pull-down device in the I/O driver and their respective driving inverters in the first stage in accordance with some embodiments.

FIG. 5 is a diagram of a driving stage of a transmitter device in accordance with some embodiments.

FIG. 6A is a diagram illustrating the connection of pre-drivers, I/O drivers, and an I/O pad in accordance with some embodiments.

FIG. 6B is a diagram illustrating a layout of an I/O driver in accordance with the embodiment of FIG. 6A.

FIG. 7 is a method for operating a transmitter circuit in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

As used herein, the term “technology node” (or “wafer node”, “process node”, “process technology node”, or “node”) refers to a parameter in a specific semiconductor manufacturing process and its design rules. For example, the technology node used herein may be defined by a minimum gate width of a chip. A smaller technology node corresponds to a smaller feature size, which in turn corresponds to smaller transistors.

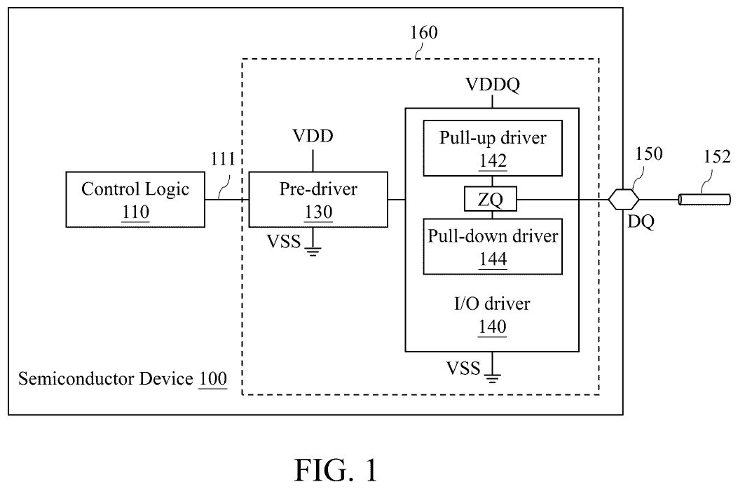

FIG. 1 is a block diagram of a semiconductor device 100 in accordance with some embodiments.

In some embodiments, the semiconductor device 100 includes a control logic 110, a pre-driver 130, an I/O driver 140, and an input/output (I/O) pad 150. The semiconductor device 100 may comprise an integrated circuit (IC) or chip in which the control logic 110 generates and distributes data to one or more high-speed interfaces. For example, semiconductor device 100 may comprise a processor or memory controller having control logic 110 with high-speed logic circuitry or may comprise a memory device (e.g., dynamic random access memory (DRAM)) having control logic 110 made up of memory storage cells. In any case, each I/O interface may use I/O driver 140 and I/O pad 150 to communicate with other ICs or devices via transmission medium 152 (e.g., a trace or bus).

In some embodiments, the semiconductor device 100 may support the LPDDR5X or future revisions. Generally, the control logic 110 and pre-driver 130 may operate in a first power domain between a power supply voltage VDD and a ground voltage VSS, and the I/O driver 140 operates in a second power domain between a power supply voltage VDDQ and the ground voltage VSS. In some embodiments, the power supply voltage VDD may range from 0.5 V to 1 V. In some embodiments, the power supply voltage VDDQ may be approximately 0.5 V.

In some embodiments, the pre-driver 130 is configured to shift signals 111 (e.g., including data signal and calibration signals) of the control logic 110 from the first power domain to the second power domain for I/O driver 140 to reliably transmit signals with a calibrated impedance. However, if the characteristic package impedance of I/O pad 150 does not match the characteristic impedance of transmission medium 152, signal reflections tend to occur, degrading signal quality. Mismatched impedance sometimes occurs as a result of process, voltage, and temperature (PVT) variation. In some embodiments, the semiconductor device 100 may include calibration circuitry (not shown) configured to calibrate the impedance (e.g., resistor ZQ) of the I/O driver 140 to compensate for PVT variation and improve signal quality.

In some embodiments, the I/O driver 140 may be referred as a post-driver of the semiconductor device 100. The I/O driver 140 may include a pull-up driver 142, a pull-down driver 144, and an output resistor ZQ. For purposes of description, the output resistor ZQ has a calibrated impedance that matches the characteristic impedance of the transmission medium 152. Further details thereof will be described later. In some embodiments, the pull-up driver 142 includes a voltage pull-up device on the voltage pull-up path of the output signal DQ at the I/O pad 150, while the pull-down driver 144 includes a voltage pull-down device on the voltage pull-down path of the output signal DQ at the I/O pad 150.

In some embodiments, the pre-driver 130 and the I/O driver 140 can be collectively referred to as a driving stage 160 of the semiconductor device 100. In some embodiments, the driver stage 160 may include N stages of pre-drivers 130 arranged in parallel, and include N stages of I/O driver 140 arranged in parallel, and the output resistor ZQ at each stage of the I/O driver 140 are shunt to serve as an equivalent output resistance at the I/O pad 150 which matches the characteristic impedance of the transmission medium 152. In some embodiments, N is a positive integer larger than 1.

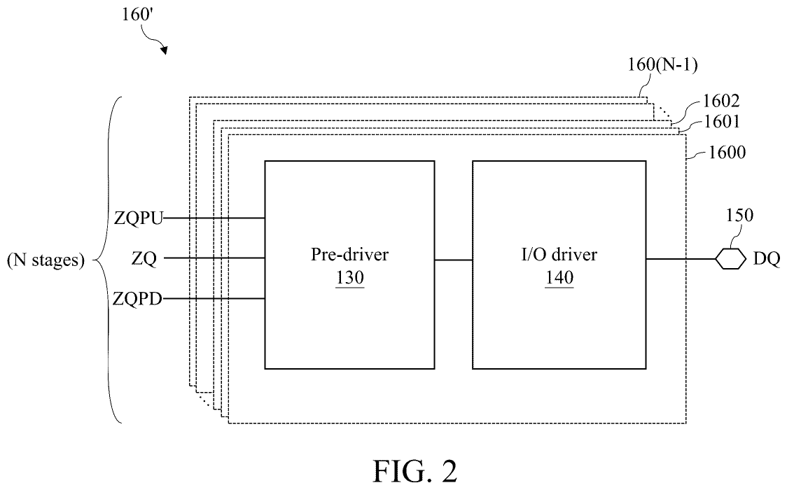

FIG. 2 is a block diagram of a driving stage of a semiconductor device in accordance with some embodiments. Please refer to FIG. 1 and FIG. 2 simultaneously.

In some embodiments, the driving stage 160′ shown in FIG. 2 includes driving stages 1600 to 160(N-1) (e.g., N stages), with each driving stage 1600 to 160(N-1) being similar to the driving stage 160 shown in FIG. 1. For simplicity, the pre-driver 130 and the I/O driver 140 of the driving stage 1600 are shown in FIG. 2.

In some embodiments, the driving stages 1600 to 160(N-1) may each receive a respective bit of a pull-up calibration signal ZQPU[N-1:0] and a respective bit of a pull-down calibration signal ZQPD[N-1:0]. The pull-up calibration signal ZQPU and the pull-down calibration ZQPD may be regarded as a first resistance calibration signal and a second resistance calibration signal, respectively. In some embodiments, the control logic 110 may include a calibration circuit (not shown) configured to perform an impedance matching process to determine a plurality of calibrated values that serves as the pull-up calibration signal ZQPU[N-1:0] and the pull-down calibration signal ZQPD[N-1:0]. For example, the driving stage 1600 may receive the least significant bit ZQPU[0] of the pull-up calibration signal ZQPU[N-1:0] and the least significant bit ZQPD[0] of the pull-down calibration signal ZQPD[N-1:0]. The driving stage 1600 may receive the second least significant bit ZQPU[1] of the pull-up calibration signal ZQPU[N-1:0] and the second least significant bit ZQPD[1] of the pull-down calibration signal ZQPD[N-1:0], and so forth. The pull-up calibration signal ZQPU[N-1:0] may be used to control the equivalent pull-up resistances of the respective driving stages 1600 to 160(N-1), and the pull-down calibration signal ZQPD[N-1:0] may be used to control the equivalent pull-down resistances of the respective driving stages 1600 to 160(N-1), thereby achieving impedance matching between the I/O pad 150 and the transmission medium 152, and optimizing signaling of the I/O drivers 140.

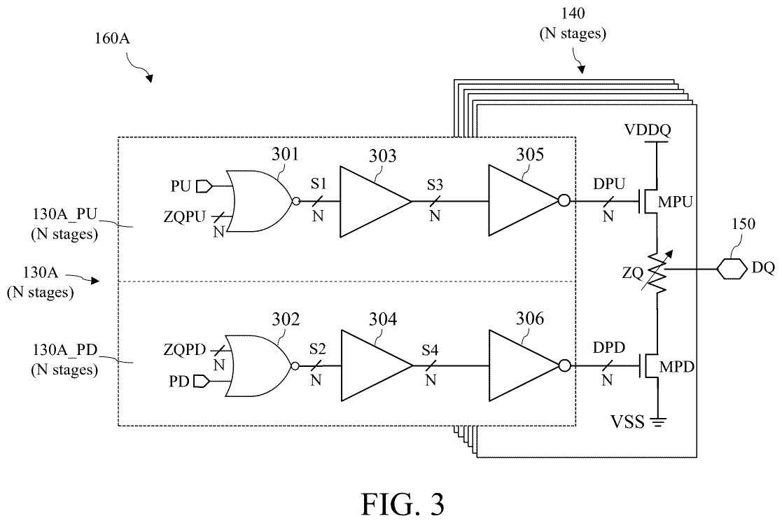

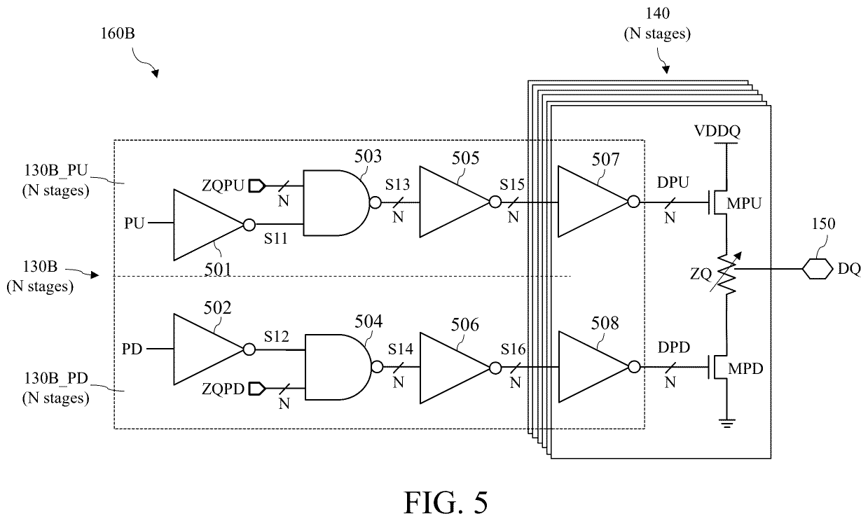

Additionally, the driving stages 1601 to 160N may receive a data signal ZQ from the control logic 110. The data signal ZQ may be transmitted to the I/O pad 150 through the driving stage 160′. In some embodiments, the data signal ZQ may serve as a data signal PU for the pull-up driver 142 of each of the driving stages 1601 to 160N, and it may also serve as a data signal PD for the pull-down driver 144 of each of the driving stages 1601 to 160N, the details of which are described with reference to FIG. 3 and FIG. 5.

FIG. 3 is a diagram of a driving stage of a transmitter circuit in accordance with some embodiments. Please refer to FIGS. 1 to 3 simultaneously.

In some embodiments, the driving stage 160A may be similar to the driving stage 160′ shown in FIG. 2, with the difference being that N stages of pre-drivers 130A are used in the driving stage 160A. In some embodiments, for brevity, the signals ZQPU, ZQPD, DPU, and DPD shown in the pre-drivers 130A and the I/O drivers 140 are N-bit signals, which are shown by respective signal names with an N-bit width. Additionally, for brevity, the circuit of the I/O driver 140 in the first stage is shown in FIG. 3.

In some embodiments, the data signal ZQ may serve as the data signal PU for the first portion 130A_PU of the pre-driver 130A in each stage, and it also serve as the data signal PD for the first portion 130A_PD of the pre-driver 130A in each stage.

In some embodiments, the upper portion 130A_PU of the pre-driver 130A includes a NOR gate 301, a buffer 303, and an inverter 305 arranged in sequence. The lower portion 130A_PD of the pre-driver 130A includes a NOR gate 302, a buffer 304, and an inverter 306 arranged in sequence. In some embodiments, the NOR gates 301-302, buffers 303-304, and inverters 305-306 in the pre-driver 130A may be operated within the first voltage domain ranging from the ground voltage VSS to the power supply voltage VDD. In some embodiments, the power supply voltage VDD may range from approximately 0.5 V to 1.0 V. In some embodiments, the I/O drivers 140 may be operate within the second voltage domain ranging from the ground voltage VSS to the power supply voltage VDDQ. In some embodiments, the power supply voltage VDDQ may be approximately 0.5 V.

In some embodiments, each of the I/O drivers 140 may include a pull-up device MPU and a pull-down device MPD, which correspond to the pull-up driver 142 and pull-down driver 144 shown in FIG. 1, respectively. The pull-up device MPU and the pull-down device MPD may be N-type transistors. In some embodiments, a gate terminal of the pull-up device MPU is coupled to an output terminal of inverter 305. A drain terminal of the pull-up device MPU is configured to receive the power supply voltage VDDQ. A source terminal of the pull-up device MPU is coupled to a first terminal of the resistor ZQ. In some embodiments, a gate terminal of the pull-down device MPD is coupled to an output terminal of inverter 306. A drain terminal of the pull-down device MPD is coupled to a second terminal of the resistor ZQ. A source terminal of the pull-down device MPD is configured to receive the ground voltage VSS.

In some embodiments, the resistor ZQ of the I/O driver 140 in each stage can be divided into a first portion and a second portion for the pull-up path and the pull-down path, respectively. Additionally, the first portion of the resistor ZQ of the I/O driver 140 in each stage is shunt to constitute an equivalent pull-up resistance for the I/O pad 150, depending on the logic state of the respective bit of the pull-up calibration signal ZQPU[N-1:0]. The second portion of the resistor ZQ of the I/O driver 140 in each stage are also shunt to constitute an equivalent pull-down resistance for the I/O pad 150. It should be noted that the pull-up calibration signal ZQPU[N-1:0] may differ from the pull-down calibration signal ZQPD[N-1:0].

In some embodiments, when the respective bit of the pull-up calibration signal ZQPU received by the NOR gate 301 of the pre-driver 130A in a specific stage is in the high logic state (e.g., “1”), the pull-up device MPU of the I/O driver 140 in the specific stage is turned off regardless of the logic state of the data signal PU, disabling the first portion of the resistor ZQ in the I/O driver 140 in the specific stage. In some embodiments, when the respective bit of the pull-up calibration signal ZQPU received by the NOR gate 301 of the pre-driver 130A in a specific stage is in the low logic state (e.g., “0”), activation of the pull-up device MPU of the I/O driver 140 in the specific stage depends on the logic state of the data signal PU. At this time, the pull-up device MPU is turned on when the data signal PU is in the low logic state (e.g., “0”), and is turned off when the data signal PU is in the high logic state (e.g., “1”). For purposes of description, when the bits ZQPU[0], ZQPU[1], and ZQPU[4] are in the high logic state (e.g., “1”) and the remaining bits in the pull-up calibration signal ZQPU[N-1:0] are in the low logic state (e.g., “0”), the first portion of the resistors ZQ in the I/O drivers 140 in the first stage, the second stage, and the fifth stage are shunt, constituting the equivalent pull-up resistance for the data signal DQ at the I/O pad 150.

Similarly, when the respective bit of the pull-down calibration signal ZQPD received by the NOR gate 302 of the pre-driver 130A in a specific stage is in the high logic state (e.g., “1”), the pull-down device MPD of the I/O driver 140 in the specific stage is turned off, disabling the second portion of the resistor ZQ in the I/O driver 140 in the specific stage. When the respective bit of the pull-down calibration signal ZQPD received by the NOR gate 302 of the pre-driver 130A in a specific stage is in the low logic state (e.g., “0”), activation of the pull-down device MPD of the I/O driver 140 in the specific stage depends on the logic state of the data signal PD. At this time, the pull-down device MPD is turned on when the data signal PD is in the low logic state (e.g., “0”), and is turned off when the data signal PU is in the high logic state (e.g., “1”). For purposes of description, when the bits ZQPD[0], ZQPD[1], and ZQPD[2] are in the high logic state (e.g., “1”) and the remaining bits in the pull-down calibration signal ZQPD[N-1:0] are in the low logic state (e.g., “0”), the second portion of the resistors ZQ in the I/O drivers 140 in the first to third stages are shunt, constituting the equivalent pull-down resistance for the I/O pad 150. It should be noted that the pull-up calibration signal ZQPU and the pull-down calibration signal ZQPD can be different, thereby separately calibrating the equivalent pull-up resistance and the equivalent pull-down resistance of the I/O drivers 140.

In some embodiments, the control logic 110 may send the respective bit of the pull-up calibration signal ZQPU[N-1:0] to the upper portion 130A_PU of the pre-driver 130A in each stage, and send the respective bit of the pull-down calibration signal ZQPD[N-1:0] to the lower portion 130A_PD of the pre-driver 130A in each stage. Specifically, the data signal PU and the respective bit ZQPU[0] may serve as the input signals of the NOR gate 301 in the upper portion 130A_PU of the pre-driver 130A in the first stage. The data signal PD and the respective bit ZQPD[0] may serve as the input signals of the NOR gate 304 in the upper portion 130A_PD of the pre-driver 130A in the first stage, and so forth.

In some embodiments, the NOR gate 301 in the upper portion 130A_PU of the pre-driver 130A in each stage receives the data signal PU and the respective bit of the pull-up calibration signal ZQPU[N-1:0] to generate signal S1 at the output terminal of the NOR gate 301. The signal S1 generated by the NOR gate 301 passes through the buffer 303 and the inverter 305 to generate the data pull-up signal (DPU) at the gate terminal of the pull-up device MPU of the I/O driver 140 in each stage. Similarly, the NOR gate 302 in the lower portion 130A_PD of the pre-driver 130A in each stage receives the data signal PD and the respective bit of the pull-up calibration signal ZQPD[N-1:0] to generate signal S2 at the output terminal of the NOR gate 302. The signal S2 generated by the NOR gate 302 passes through the buffer 304 and the inverter 306 to generate the data pull-down signal (DPD) at the gate terminal of the pull-down device MPD of the I/O driver 140 in each stage.

In some embodiments, the data pull-up signal DPU generated by the inverter 305 at the gate terminal of the pull-up device MPU in the I/O driver 140 may have the same logic state as the data signal PU received by the pre-driver 130A in the corresponding stage. Similarly, the data pull-down signal DPD generated by the inverter 306 at the gate terminal of the pull-down device MPD in the I/O driver 140 may have the same logic state as the data signal PD received by the pre-driver 130A in the corresponding stage.

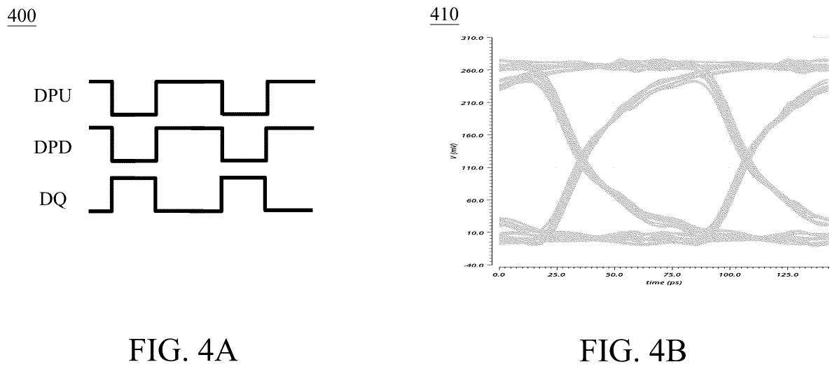

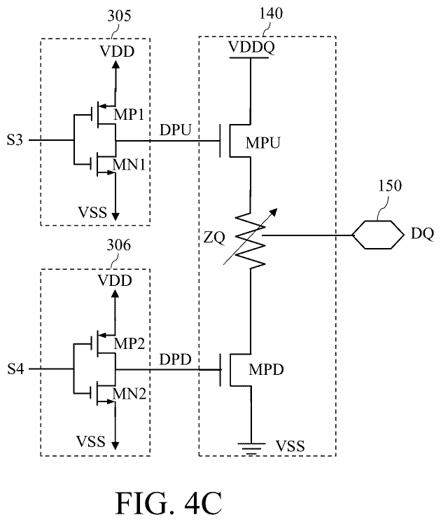

It should be noted that the data signals PU and PD are substantially the same since they are from the data signal ZQ generated by the control logic 110. The data signal PU is propagated to the I/O driver 140 through the NOR gate 301, buffer 303, and inverter 305 to drive the pull-up device MPU for the data signal DQ at the I/O pad. The data signal PD is propagated to the I/O driver 140 through the NOR gate 302, buffer 305, and inverter 306 to drive the pull-down device MPD for the data signal DQ at the I/O pad 150. Furthermore, the logic states of the data pull-up signal DPU and the data pull-down signal DPD may substantially align with each other, and the logic state of the data signal DQ may be inverse to those of the data pull-up signal DPU and the data pull-down signal DPD, as shown by the waveform diagram 400 in FIG. 4A.

FIG. 4C is a circuit diagram illustrating the pull-up device MPU and the pull-down device MPD in the I/O driver 140 and their respective driving inverters 305 and 306 in the first stage in accordance with some embodiments.

In some embodiments, the buffer 303 and inverter 305 may increase the driving strength of the pull-up device MPU. The buffer 304 and inverter 306 may increase the driving strength of the pull-down device MPD. For example, the buffers 303 and 304 in the pre-driver 130A each may be implemented by two inverters connected in series. Additionally, the inverter 305 in the pre-driver 130A is a CMOS (complementary metal oxide semiconductor) inverter, which includes a p-type transistor MP1 and an n-type transistor MN1, as shown in FIG. 4C. Similarly, the inverter 306 in the pre-driver 130A is another CMOS inverter, which includes a p-type transistor MP2 and an n-type transistor MN2, as shown in FIG. 4C.

Specifically, when signals S3 and S4 are in the low logic state (e.g., “0”), transistors MP1 and MP2 are turned on. Accordingly, the voltage level of the data pull-up signal DPU is pulled up to the power supply voltage VDD (e.g., higher than VDDQ) minus one stage of source-drain voltage of transistor MP1. Since the source-drain voltage of transistor MP1 is very low when transistor MP1 is turned on, the voltage level of the data pull-up signal DPU (e.g., gate voltage of the pull-up device MPU) is very close to the power supply voltage VDD, which is capable of fully turning on the pull-up device MPU when pulling up the data signal DQ at the I/O pad 150 to the power supply voltage VDDQ. Similarly, since the source-drain voltage of transistor MP2 is very low when transistor MP2 is turned on, the voltage level of the data pull-down signal DPU (e.g., gate voltage of the pull-down device MPU) is very close to the power supply voltage VDD, which is capable of fully turning on the pull-down device MPD when pulling down the data signal DQ to the ground voltage VSS.

It should be noted that the gate voltages of the pull-up device MPU and the pull-down device MPD can be pulled up to the power supply voltage VDD through one stage of p-type transistor of the respective inverters 305 and 306, or pulled down to the ground voltage VSS through one stage of n-type transistor of the respective inverters 305 and 306. Additionally, the drain terminal of the pull-up device MPU is coupled to the power supply voltage VDDQ, while the source terminal of the pull-down device MPD is coupled to the ground voltage VSS. Accordingly, the I/O driver 140 can provide a high driving strength for the data signal DQ at the I/O pad 150. For example, as shown by the eye diagram 410 of the data signal DQ in FIG. 4B, the eye width of the data signal DQ is approximately 0.809 unit interval (UI) (e.g., approximately 80.9 picoseconds). Accordingly, the data rate of the data signal DQ at the I/O pad 150 can reach approximately 14 Gbps, which meets the data rate requirements of the LPDDR5X and LPDDR6 standards.

In some approaches, a NOR gate may be connected to gate terminals of the pull-up device and the pull-down device in the I/O driver. However, a CMOS NOR gate includes two stages of p-type transistors connected in series (i.e., stacked structure) and one stage of two n-type transistors arranged in parallel. This indicates that the gate voltages of the pull-up device and the pull-down device in these approaches are lower compared to those of the pull-up device MPU and the pull-down device MPD in FIG. 4C, resulting in a lower driving strength (e.g., a lower driving current) of the I/O driver in these approaches, which may fail to reach such a high data rate of LPDDR5X or future revisions.

In some other approaches, the pull-up device in the I/O driver is coupled to the power supply voltage VDDQ through a pull-up control transistor, and the pull-down device in the I/O driver is coupled to the ground voltage VSS through a pull-down control transistor. This indicates that a stacked structure is used for the voltage pull-up path of the data signal DQ, and another stacked structure is used for the voltage pull-down path of the data signal DQ, resulting in a lower driving strength (e.g., a lower driving current) of the pull-up device and the pull-down device in these approaches compared to that of the pull-up device MPU and the pull-down device MPD in FIG. 4C.

FIG. 5 is a diagram of a driving stage of a transmitter device in accordance with some embodiments. Please refer to FIGS. 1, 2, and 5 simultaneously.

In some embodiments, the driving stage 160B may be similar to the driving stage 160A shown in FIG. 3, with the difference being that N stages of pre-drivers 130B are used in the driving stage 160B. In some embodiments, for brevity, the signals ZQPU, ZQPD, DPU, and DPD shown in the pre-drivers 130B and the I/O drivers 140 are N-bit signals, which are shown by respective signal names with an N-bit width. Additionally, for brevity, the circuit of the I/O driver 140 in the first stage is shown in FIG. 5.

In some embodiments, the data signal ZQ may serve as the data signal PU for the first portion 130B_PU of the pre-driver 130B in each stage, and it also serve as the data signal PD for the first portion 130B_PD of the pre-driver 130AB in each stage.

In some embodiments, the upper portion 130B_PU of the pre-driver 130B includes an inverter 501, a NAND gate 503, and inverters 505 and 507 arranged in sequence. The lower portion 130B_PD of the pre-driver 130B includes an inverter 502, a NAND gate 504, and inverters 506 and 508 arranged in sequence. In some embodiments, the inverters 501-502 and 505-508 and NAND gates 503-504 in the pre-driver 130B may be operated within the first voltage domain ranging from the ground voltage VSS to the power supply voltage VDD. In some embodiments, the power supply voltage VDD may range from approximately 0.5 V to 1.0 V. In some embodiments, the I/O drivers 140 may be operate within the second voltage domain ranging from the ground voltage VSS to the power supply voltage VDDQ. In some embodiments, the power supply voltage VDDQ may be approximately 0.5 V.

In some embodiments, there are four inversions of the data signal PU along the path from the input terminal of the inverter 501 to the gate terminal of the pull-up device MPU, and thus the data pull-up signal DPU may have the same logic state as the data signal PU when the respective bit of the pull-up calibration signal ZQPU is in the high logic state (e.g., “1”). In some embodiments, when the respective bit of the pull-up calibration signal ZQPU received by the inverter 501 of the pre-driver 130B in a specific stage is in the high logic state (e.g., “1”), the activation of the pull-up device MPU of the I/O driver 140 in the specific stage depends on the logic state of the data signal PU. For brevity, given that the specific stage is the first stage, when the respective bit ZQPU[0]=1 and the data signal PU=1, the pull-up device MPU of the I/O driver 140 in the specific stage is turned on. When the respective bit ZQPU[0]=1 and the data signal PU=0, the pull-up device MPU of the I/O driver 140 in the specific stage is turned off. Additionally, when the respective bit ZQPU[0]=0, the pull-up device MPU of the I/O driver 140 in the specific stage is turned on regardless of the logic state of the data signal PU, enabling the first portion of the resistor ZQ in the I/O driver 140 in the specific stage.

In some embodiments, there are also four inversions of the data signal PD along the path from the input terminal of the inverter 502 to the gate terminal of the pull-down device MPD, and thus the data pull-down signal DPD may have the same logic state as the data signal PU when the respective bit of the pull-down calibration signal ZQPD is in the high logic state (e.g., “1”). In some embodiments, when the respective bit of the pull-down calibration signal ZQPD received by the inverter 502 of the pre-driver 130B in a specific stage is in the high logic state (e.g., “1”), the activation of the pull-down device MPD of the I/O driver 140 in the specific stage depends on the logic state of the data signal PD. For brevity, given that the specific stage is the first stage, when the respective bit ZQPD[0]=1 and the data signal PD=1, the pull-down device MPD of the I/O driver 140 in the specific stage is turned on. When the respective bit ZQPD[0]=1 and the data signal PD=0, the pull-down device MPD of the I/O driver 140 in the specific stage is turned off. Additionally, when the respective bit ZQPD[0]=0, the pull-down device MPD of the I/O driver 140 in the specific stage is turned on regardless of the logic state of the data signal PD, enabling the second portion of the resistor ZQ in the I/O driver 140 in the specific stage.

In some embodiments, the inverters 505 and 507 may increase the driving strength of the pull-up device MPU. The inverters 506 and 508 may increase the driving strength of the pull-down device MPD. For example, each of the inverters 505 and 507 in the pre-driver 130B is a CMOS (complementary metal oxide semiconductor) inverter, which is similar to the inverter 305 shown in FIG. 4C. Similarly, each of the inverters 506 and 508 in the pre-driver 130B is also a CMOS inverter, which is similar to the inverter 306 shown in FIG. 4C.

Accordingly, the gate voltages (e.g., signals DPU and DPD) of the pull-up device MPU and the pull-down device MPD can be pulled up to the power supply voltage VDD through one stage of p-type transistor of the respective inverters 507 and 508, or pulled down to the ground voltage VSS through one stage of n-type transistor of the respective inverters 507 and 508. Therefore, the I/O driver 140 shown in FIG. 5 can provide a high driving strength for the data signal DQ at the I/O pad 150, the details of which can be referred to in the embodiment of FIG. 4C.

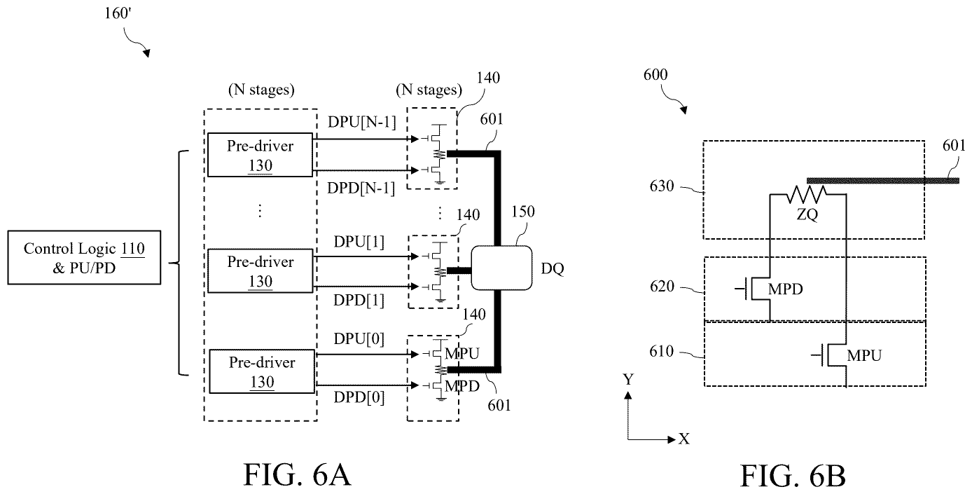

FIG. 6A is a diagram illustrating the connection of pre-drivers, I/O drivers, and an I/O pad in accordance with some embodiments. FIG. 6B is a diagram illustrating a layout of an I/O driver in accordance with the embodiment of FIG. 6A.

In some embodiments, the driving stage 160′ shown in FIG. 2 includes N stages of the pre-drivers 130 and I/O drivers 140. The pre-driver 130 and I/O driver 140 within each stage can determine, based on the data signals PU and PD and the respective bit of signals ZQPU and ZQPD, the pull-up resistance and pull-down resistance of each stage. Additionally, the resistor ZQ in each stage is electrically connected to the I/O pad 150 through a respective metal wire 601 with a large width, thereby obtaining the equivalent pull-up resistance and equivalent pull-down resistance (e.g., calibrated pull-up resistance and calibrated pull-down resistance) for the data signal DQ at the I/O pad.

In some embodiments, the layout of an I/O driver 140 shown in FIG. 6A is illustrated by layout diagram 600 in FIG. 6B. For example, layout diagram 600 includes a first row 610, a second row 620, and a third row 630. The pull-up device MPU is positioned or formed on the first row 610 (e.g., a first active region) of a substrate (not shown), and a source/drain terminal of the pull-up device MPU is connected to a first terminal of the resistor ZQ. The pull-down device MPD is positioned or formed on the second row 620 (e.g., a second active region) of the substrate, and a source/drain terminal of the pull-down device MPD is connected to a second terminal of the resistor ZQ.

In some embodiments, the resistor ZQ is formed on the third row 630 of the substrate, and the respective metal wire 601 is electrically connected to a midway point of the resistor ZQ, as shown in FIG. 6B. It should be noted that the ZQ resistor in each I/O driver 140 is electrically connected to the I/O pad 150 through the respective metal wire 601. As such, the layout diagram of the N stages of I/O drivers 140 may include the layout diagram 600B repeated for N times along a first direction (e.g., direction X).

In some embodiments, the devices, logic gates, and/or transistors within the control logic 110, pre-drivers 130, and I/O drivers 140 are fabricated in a front-end-of-line (FEOL) process. Additionally, the resistor ZQ in each I/O driver 140 is an on-die termination (ODT) resistor fabricated in a back-end-of-line (BEOL) process.

In some embodiments, the pull-up device MPU and the pull-down MPD are n-type transistors. In some embodiments, the pull-down device MPD is an n-type transistor, and the pull-up device MPU is a p-type transistor or a combination of a p-type transistor and n-type transistor arranged in a cascode structure.

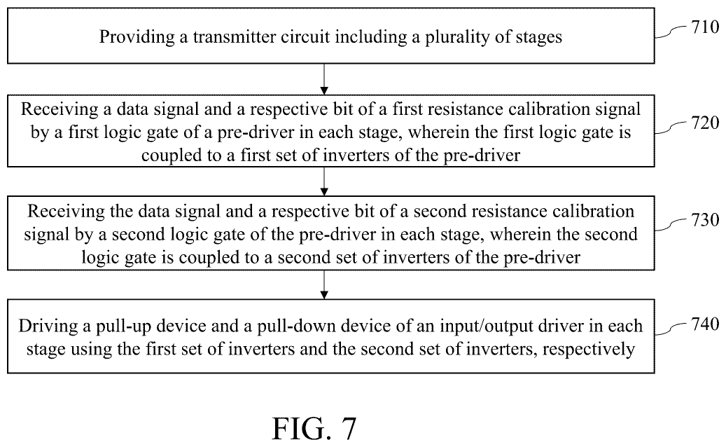

FIG. 7 is a method for operating a transmitter circuit in accordance with some embodiments. Please refer to FIGS. 1, 3, and 7 simultaneously. Method 700 includes operations 710, 720, 730, and 740. The order of operations 710 to 740 can be exchanged. Additional operations can be added before or after each of the operations 710 to 740.

At operation 710, a transmitter circuit including a plurality of stages is provided. In some embodiments, the transmitter circuit may be part of the semiconductor device 100 shown in FIG. 1, and the transmitter circuit may include a plurality of stages, such as driving stages 1600 to 160(N-1) shown in FIG. 2.

At operation 720, a data signal and a respective bit of a first resistance calibration signal are received by a first logic gate of a pre-driver in each stage, wherein the first logic gate is coupled to a first set of inverters of the pre-driver. In some embodiments, the first logic gate may refer to the NOR gate 301 shown in FIG. 3, and the first set of inverters may include buffer 303 (e.g., two inverters connected in series) and inverter 305.

At operation 730, the data signal and a respective bit of a second resistance calibration signal are received by a second logic gate of the pre-driver in each stage, wherein the second logic gate is coupled to a second set of inverters of the pre-driver. In some embodiments, the first logic gate may refer to the NOR gate 302 shown in FIG. 3, and the second set of inverters may include buffer 304 (e.g., two inverters connected in series) and inverter 306.

At operation 740, a pull-up device and a pull-down device of an input/output driver in each stage are driven using the first set of inverters and the second set of inverters, respectively. In some embodiments, inverter 305 within the first set of inverters is configured to drive the pull-up device MPU in the I/O driver 140 in each stage, while inverter 306 within the second set of inverters is configured to drive the pull-down device MPD in the I/O driver 140 in each stage. Additionally, the inverter 305 and inverter 306 each includes one stage of p-type transistor and one stage of n-type transistor. The pull-up device MPU has its drain terminal coupled to the power supply voltage VDDQ, and the pull-down device MPD has its source terminal coupled to the ground voltage VSS. Accordingly, the driving strength of the I/O drivers 140 can be improved, thereby achieving high data rate of the data signal DQ at the I/O pad 150.

An aspect of the present disclosure provides a transmitter circuit, which includes a control logic and a driving circuit. The control logic is configured to generate a data signal, a first resistance calibration signal, and a second resistance calibration signal. The driving circuit includes a plurality of stages, and each stage includes an input/output (I/O) driver and a pre-driver. The I/O driver includes a pull-up device and a pull-down device coupled to an I/O pad of the transmitter circuit through a first portion and a second portion of a resistor, respectively. The pre-driver includes a first logic gate which operates according to a respective bit of the first resistance calibration signal and the data signal; a second logic gate which operate according to a respective bit of the second resistance calibration signal and the data signal; first inverters configured to drive the pull-up device; and second inverters configured to drive the pull-down device.

Another aspect of the present disclosure provides a transmitter circuit, which includes a control logic and a driving circuit. The control logic is configured to generate a data signal, a first resistance calibration signal, and a second resistance calibration signal. The driving circuit, includes a plurality of stages, and each stage includes a first circuit, a second circuit, and a resistor. The first circuit includes a first inverter, a first logic gate, a second inverter, a third inverter, and a pull-up device connected in series. The second circuit includes a fourth inverter, a second logic gate, a fifth inverter, a sixth inverter, and a pull-down device connected in series. The resistor is coupled between the pull-up device and the pull-down device, and electrically connected to an input/output (I/O) pad of the transmitter circuit. The first inverter is configured to receive the data signal, and the third inverter is configured to drive the pull-up device. The fourth inverter is configured to receive the data signal, and the sixth inverter is configured to drive the pull-down device.

Yet another aspect of the present disclosure provides a method. A transmitter circuit including a plurality of stages is provided. A data signal and a respective bit of a first resistance calibration signal are received by a first logic gate of a pre-driver in each stage. The first logic gate is coupled to a first set of inverters of the pre-driver. The data signal and a respective bit of a second resistance calibration signal are received by a second logic gate of the pre-driver in each stage. The second logic gate is coupled to a second set of inverters of the pre-driver. A pull-up device and a pull-down device of an input/output driver in each stage are driven using the first set of inverters and the second set of inverters, respectively.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A transmitter circuit, comprising:
a control logic, configured to generate a data signal, a first resistance calibration signal, and a second resistance calibration signal; and
a driving circuit, comprising a plurality of stages, each stage comprising:
an input/output (I/O) driver, comprising: a pull-up device, a pull-down device, and a resistor, wherein the pull-up device and the pull-down device are coupled to an I/O pad of the transmitter circuit through a first portion and a second portion of the resistor, respectively; and
a pre-driver, comprising:
a first logic gate, configured to operate according to a respective bit of the first resistance calibration signal and the data signal;
a second logic gate, configured to operate according to a respective bit of the second resistance calibration signal and the data signal;
a first set of inverters, coupled between the first logic gate and the pull-up device, and configured to drive the pull-up device; and
a second set of inverters, coupled between the second logic gate and the pull-down device, and configured to drive the pull-down device.

2. The transmitter circuit of claim 1, wherein the control logic and the pre-driver in each stage operate within a first voltage domain, and the I/O driver in each stage operate within a second voltage domain narrower than the first voltage domain.

3. The transmitter circuit of claim 2, wherein:
the first voltage domain ranges from a ground voltage to a first power supply voltage;
the second voltage domain ranges from the ground voltage to a second power supply voltage; and
the second power supply voltage is lower than the first power supply voltage.

4. The transmitter circuit of claim 3, wherein the first power supply voltage is approximately 1 V, and the second power supply voltage is approximately 0.5 V.

5. The transmitter circuit of claim 3, wherein:
the pull-up device in each stage comprises a gate terminal coupled to the first set of inverters, a first terminal configured to receive the second power supply voltage, and a second terminal coupled to a first terminal of the resistor in each stage; and
the pull-down device in each stage comprises a gate terminal coupled to the second set of inverters, a first terminal coupled to a second terminal of the resistor in each stage, and a second terminal configured to receive the ground voltage.

6. The transmitter circuit of claim 5, wherein the pull-up device and the pull-down device of the I/O driver in each stage comprise n-type transistors.

7. The transmitter circuit of claim 5, wherein the pull-up device and the pull-down device of the I/O driver in each stage comprise a p-type transistor and an n-type transistor, respectively.

8. The transmitter circuit of claim 5, wherein the resistor of the I/O driver in each stage is coupled to the I/O pad through a respective metal wire.

9. The transmitter circuit of claim 8, wherein the resistor of the I/O driver in each stage is fabricated in a back-end-of-line (BEOL) process, and the pull-up device and the pull-down device of the I/O driver in each stage are fabricated in a front-end-of-line (FEOL) process.

10. The transmitter circuit of claim 5, wherein:
the first set of inverters of the pre-driver in each stage comprises a first inverter, a second inverter, and a third inverter connected in series, and an output terminal of the third inverter is coupled to the gate terminal of the pull-up device of the I/O driver; and
the second set of inverters of the pre-driver in each stage comprises a fourth inverter, a fifth inverter, and a sixth inverter connected in series, and an output terminal of the sixth inverter is coupled to the gate terminal of the pull-down device of the I/O driver.

11. The transmitter circuit of claim 10, wherein the first inverter, the second inverter, the third inverter, the fourth inverter, the fifth inverter, and the sixth inverter are CMOS (complementary metal oxide semiconductor) inverters.

12. The transmitter circuit of claim 10, wherein:
the first logic gate of the pre-driver in each stage comprises a first NOR gate coupled to the first inverter and configured to receive the data signal and the respective bit of the first resistance calibration signal; and
the second logic gate of the pre-driver in each stage comprises a second NOR gate coupled to the fourth inverter and configured to receive the data signal and the respective bit of the second resistance calibration signal.

13. The transmitter circuit of claim 12, wherein:
the first inverter and the second inverter of the pre-driver in each stage form a first buffer; and
the fourth inverter and the fifth inverter of the pre-driver in each stage form a second buffer.

14. The transmitter circuit of claim 12, wherein the first resistance calibration signal and the second resistance calibration signal are used to calibrate an equivalent impedance of the I/O drivers in the plurality of stages.

15. A transmitter circuit, comprising:
a control logic, configured to generate a data signal, a first resistance calibration signal, and a second resistance calibration signal; and
a driving circuit, comprising a plurality of stages, each stage comprising:
a first circuit, comprising: a first inverter, a first logic gate, a second inverter, a third inverter, and a pull-up device connected in series;
a second circuit, comprising: a fourth inverter, a second logic gate, a fifth inverter, a sixth inverter, and a pull-down device connected in series; and
a resistor coupled between the pull-up device and the pull-down device, and electrically connected to an input/output (I/O) pad of the transmitter circuit,
wherein the first inverter is configured to receive the data signal, and the third inverter is configured to drive the pull-up device,
wherein the fourth inverter is configured to receive the data signal, and the sixth inverter is configured to drive the pull-down device.

16. The transmitter circuit of claim 15, wherein the first logic gate and the second logic gate in each stage comprise NAND gates.

17. The transmitter circuit of claim 15, wherein:
the first logic gate in each stage is configured to receive a respective bit of the first resistance calibration signal and a first signal inverted from the data signal by the first inverter; and
the second logic gate in each stage is configured to receive a respective bit of the second resistance calibration signal and a second signal inverted from the data signal by the fourth inverter.

18. The transmitter circuit of claim 15, wherein:
the control logic, the first inverter, the second inverter, the third inverter, the fourth inverter, the fifth inverter, the sixth inverter, the first logic gate, and the second logic gate operate within a first voltage domain; and
the pull-up device and the pull-down device operate within a second voltage domain narrower than the first voltage domain.

19. The transmitter circuit of claim 17, wherein:
the first voltage domain ranges from a ground voltage to a first power supply voltage;
the second voltage domain ranges from the ground voltage to a second power supply voltage; and
the second power supply voltage is lower than the first power supply voltage.

20. A method, comprising:
providing a transmitter circuit comprising a plurality of stages;
receiving a data signal and a respective bit of a first resistance calibration signal by a first logic gate of a pre-driver in each stage, wherein the first logic gate is coupled to a first set of inverters of the pre-driver;
receiving the data signal and a respective bit of a second resistance calibration signal by a second logic gate of the pre-driver in each stage, wherein the second logic gate is coupled to a second set of inverters of the pre-driver; and
driving a pull-up device and a pull-down device of an input/output driver in each stage using the first set of inverters and the second set of inverters, respectively.
